(19) United States
(12) Patent Application Publication
(10) Pub. No.: US 2016/0203855 A1
(43) Pub. Date: Jul. 14, 2016

(54) MEMORY DEVICE, RELATED METHOD, AND RELATED ELECTRONIC DEVICE

(71) Applicant: Semiconductor Manufacturing International (Shanghai) Corporation, Shanghai (CN)

(72) Inventor: Gong ZHANG, Shanghai (CN)

(21) Appl. No.: 14/986,228

(22) Filed: Dec. 31, 2015

(30) Foreign Application Priority Data
Jan. 14, 2015 (CN) 201510018694.6

(51) Int. Cl. G11C 11/412; G11C 5/06; G11C 11/419; H01L 27/11; G11C 11/418

(52) U.S. Cl. CPC G11C 11/412; H01L 27/1104; G11C 11/418; G11C 11/419; G11C 5/063

(57) ABSTRACT

A memory device may include a first p-channel transistor, a first n-channel transistor, a first inverter, and a first access transistor. A source terminal of the first p-channel transistor is electrically connected to a first power supply terminal. A source terminal of the first n-channel transistor is electrically connected to a second power supply terminal. A first source terminal of the first inverter is electrically connected, without through any intervening transistor, to a drain terminal of the first p-channel transistor. A second source terminal of the first inverter is electrically connected to a drain terminal of the first n-channel transistor. A drain terminal of the first access transistor is electrically connected to an output terminal of the first inverter. A gate terminal of the first access transistor is electrically connected to a gate terminal of the first p-channel transistor.

### CROSS-REFERENCE TO RELATED APPLICATION

This application claims priority to and benefit of Chinese Patent Application No. 201510018694.6, filed on 14 Jan. 2015; the Chinese Patent Application is incorporated herein by reference in its entirety.

### BACKGROUND OF THE INVENTION

The technical field is related to a memory device, a method for operating the memory device, and an electronic device that includes the memory device.

A memory device may be used in write operations for storing data and may be used in read operations for retrieving data. A write noise margin and/or a write speed of a memory device may significantly affect performance of the memory device.

### SUMMARY

An embodiment may be related to a memory device. The memory device may include a first power supply terminal, a second power supply terminal, a first p-channel transistor, a first n-channel transistor, a first inverter, and a first access transistor. The first power supply terminal may receive a first voltage. The second power supply terminal may receive a second voltage. A source terminal of the first p-channel transistor may be electrically connected to the first power supply terminal. A source terminal of the first n-channel transistor may be electrically connected to the second power supply terminal. A first source terminal of the first inverter may be electrically connected, through no intervening transistor, to a drain terminal of the first p-channel transistor. A second source terminal of the first inverter may be electrically connected, not through any intervening transistor, to a drain terminal of the first n-channel transistor. A drain terminal of the first access transistor may be electrically connected to an output terminal of the first inverter. A gate terminal of the first access transistor may be electrically connected to a gate terminal of the first p-channel transistor.

The memory device may include a first word line and a first bit line. The first word line may be electrically connected to both the gate terminal of the first access transistor and the gate terminal of the first p-channel transistor. The first bit line may be electrically connected to the source terminal of the first access transistor.

The memory device may include a second word line. The second word line may be electrically connected to a gate terminal of the first n-channel transistor.

The first inverter may include a second p-channel transistor. A source terminal of the second p-channel transistor may be the first source terminal of the first inverter and may be electrically connected to the drain terminal of the first p-channel transistor.

The memory device may include a second inverter and a second access transistor. A first source terminal of the second inverter may be electrically connected to the source terminal of the first p-channel transistor. A second source terminal of the second inverter may be electrically connected to the source terminal of the first n-channel transistor. A drain terminal of the second access transistor may be electrically connected to both an output terminal of the second inverter and an input terminal the first inverter.

The second inverter may include a third p-channel transistor. A source terminal of the third p-channel transistor may be the first source terminal of the second inverter and may be electrically connected to the source terminal of the first p-channel transistor.

The first inverter may include a second n-channel transistor. A source terminal of the second n-channel transistor may be the second source terminal of the first inverter and may be electrically connected to the drain terminal of the first n-channel transistor.

The second inverter may include a third n-channel transistor. A source terminal of the third n-channel transistor may be the second source terminal of the second inverter and may be electrically connected to the source terminal of the first n-channel transistor.

A gate terminal of the second access transistor may be electrically connected to both the gate terminal of the first p-channel transistor and the gate terminal of the first access transistor.

An embodiment may be related to a method for operating a memory device. The method may include the following steps: providing a first copy of a first voltage to a source terminal of a first p-channel transistor, wherein the memory device may include the first p-channel transistor; providing a first copy of a second voltage to a source terminal of a first n-channel transistor, wherein the memory device may include the first n-channel transistor; providing a first signal to a source terminal of a first access transistor, wherein the memory device comprises the first access transistor, and wherein a first node of the memory device is electrically connected to a drain terminal of the first access transistor; and when providing the first signal to the source terminal of the first access transistor, providing a first copy of a second signal to a gate terminal of the first access transistor, providing a second copy of the second signal to a gate terminal of the first p-channel transistor, and providing a third signal to a gate terminal of the first n-channel transistor.

The first copy of the second signal may cause the first access transistor to turn on. The second copy of the second signal may cause the first p-channel transistor to turn off. The third signal may cause the first n-channel transistor to turn off.

The method may include the following steps: in a write operation, setting the second signal to have the first value and setting the third signal to have the second value. The second value may be unequal to the first value.

The method may include the following steps: when the first node of the memory device corresponds to a first value, setting the first signal to have a second value, setting the second signal to have the first value, and setting the third signal to have the second value to cause the first node of the memory to correspond to the second value. The second value may be unequal to the first value.

The method may include the following steps: when the first node of the memory device corresponds to a first value, setting the first signal to have a second value, setting the second signal to have the second value, and setting the third signal to have the first value to cause the first node of the memory to correspond to the second value. The second value may be unequal to the first value.

The first node of the memory device may be an output terminal of a first inverter and may be electrically connected to an input terminal of a second inverter. A second node of the memory device may be an output of the second inverter and may be electrically connected to an input terminal of the first inverter. The memory device may include the first inverter and the second inverter. A first source terminal of the first inverter may be electrically connected to a drain terminal of the first p-channel transistor. A second source terminal of the first inverter may be electrically connected to a drain terminal of the first n-channel transistor.

A first source terminal of the second inverter may be electrically connected to a source terminal of the first p-channel transistor. A second source terminal of the second inverter may be electrically connected to a source terminal of the first n-channel transistor.

The method may include the following steps: providing a second copy of the first voltage to a first source terminal of the second inverter; and providing a second copy of the second voltage to a second source terminal of the second inverter.

The method may include the following step: when providing the first signal to the source terminal of the first access transistor, providing a third copy of the second signal to a gate terminal of a second access transistor. The memory device may include the second access transistor.

The method may include the following steps: providing the second signal through a first word line, wherein the first word line may be electrically connected to each of the gate terminal of the first p-channel transistor and the gate terminal of the first access transistor; and providing the third signal though a second word line, wherein the second word line may be electrically connected to the gate terminal of the first n-channel transistor and may be insulated from the first word line.

An embodiment may be related to an electronic device. The electronic device may include an electronic component and a memory device electrically connected to the electronic component. The memory device may have one or more aforementioned features.

According to embodiments, a memory device may include a p-channel transistor and an n-channel transistor that are configured to facilitate write operations of the memory device. Therefore, a satisfactory write speed and/or a satisfactory write margin of the memory device may be achieved. Advantageously, satisfactory performance of the memory device (and satisfactory performance of an electronic device that includes the memory device) may be substantially attained.

The above summary is related to some of many embodiments of the invention disclosed herein and is not intended to limit the scope of the invention.

### BRIEF DESCRIPTION OF THE DRAWINGS

FIG. 1 shows a schematic diagram (e.g., a schematic circuit diagram) that illustrates elements and/or structures in a memory device in accordance with one or more embodiments.

FIG. 2 shows a schematic flowchart that illustrates steps in a method for operating a memory device in accordance with one or more embodiments.

FIG. 3 shows a schematic block diagram that illustrates elements in an electronic device in accordance with one or more embodiments.

### DETAILED DESCRIPTION

Example embodiments are described with reference to the accompanying drawings. As those skilled in the art would realize, the described embodiments may be modified in various different ways, all without departing from the spirit or scope. Embodiments may be practiced without some or all of these specific details. Well known process steps and/or structures may not have been described in detail in order to not unnecessarily obscure described embodiments.

The drawings and description are illustrative and not restrictive. Like reference numerals may designate like (e.g., analogous or identical) elements in the specification. Repetition of description may be avoided.

The relative sizes and thicknesses of elements shown in the drawings are for facilitate description and understanding, without limiting possible embodiments. In the drawings, the thicknesses of some layers, films, panels, regions, etc., may be exaggerated for clarity.

Illustrations of example embodiments in the figures may represent idealized illustrations. Variations from the shapes illustrated in the illustrations, as a result of, for example, manufacturing techniques and/or tolerances, may be possible. Thus, the example embodiments should not be construed as limited to the shapes or regions illustrated herein but are to include deviations in the shapes. For example, an etched region illustrated as a rectangle may have rounded or curved features. The shapes and regions illustrated in the figures are illustrative and should not limit the scope of the example embodiments.

Although the terms “first”, “second”, etc. may be used herein to describe various elements, these elements should not be limited by these terms. These terms may be used to distinguish one element from another element. Thus, a first element discussed below may be termed a second element without departing from embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

If a first element (such as a layer, film, region, or substrate) is referred to as being “on”, “neighboring”, “connected to”, or “coupled with” a second element, then the first element can be directly on, directly neighboring, directly connected to, or directly coupled with the second element, or an intervening element may also be present between the first element and the second element. If a first element is referred to as being “directly on”, “directly neighboring”, “directly connected to”, or “directed coupled with” a second element, then no intended intervening element (except environmental elements such as air) may be provided between the first element and the second element.

Spatially relative terms, such as “beneath”, “below”, “lower”, “above”, “upper”, and the like, may be used herein for ease of description to describe one element or feature's spatial relationship to another element(s) or feature(s) as illustrated in the figures. It will be understood that the spatially relative terms may encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein should be interpreted accordingly.

The terminology used herein is for the purpose of describing particular embodiments and is not intended to limit the embodiments. As used herein, the singular forms, “a”, “an”, and “the” may indicate plural forms as well, unless the context clearly indicates otherwise. The terms “includes” and/or “including”, when used in this specification, may specify the presence of stated features, integers, steps, operations, elements, and/or components, but may not preclude the presence or addition of one or more other features, integers, steps, operations, elements, components, and/or groups.

Unless otherwise defined, terms (including technical and scientific terms) used herein have the same meanings as commonly understood by one of ordinary skill in the art. Terms, such as those defined in commonly used dictionaries, should be interpreted as having meanings that are consistent with their meanings in the context of the relevant art and should not be interpreted in an idealized or overly formal sense unless expressly so defined herein.

The term “connect” may mean “electrically connect”. The term “insulate” may mean “electrically insulate”. The term “conductive” may mean “electrically conductive”. The term “electrically connected” may mean “electrically connected without any intervening transistors”.

Unless explicitly described to the contrary, the word “comprise” and variations such as “comprises”, “comprising”, “include”, or “including” may imply the inclusion of stated elements but not the exclusion of other elements.

Various embodiments, including methods and techniques, are described in this disclosure. Embodiments may also cover an article of manufacture that includes a non-transitory computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, embodiments may also cover apparatuses for practicing embodiments. Such apparatus may include circuits, dedicated and/or programmable, to carry out operations pertaining to embodiments. Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to embodiments.

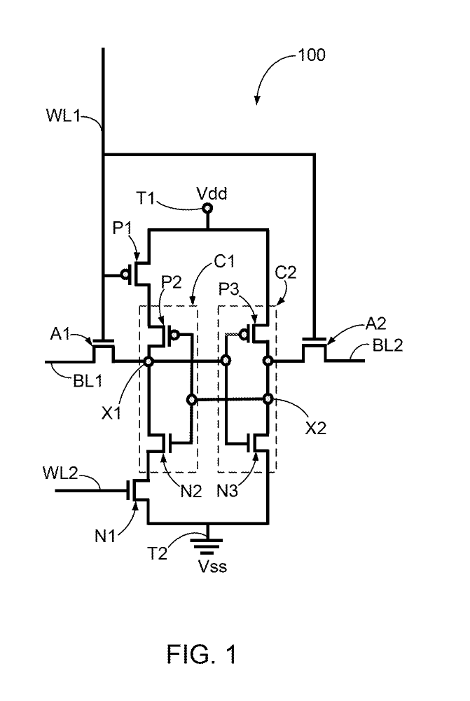

FIG. 1 shows a schematic diagram (e.g., a schematic circuit diagram) that illustrates elements and/or structures in a memory device 100 in accordance with one or more embodiments. The memory device 100 may be a static random-access memory (SRAM) device. The memory device 100 may include a power supply terminal T1, a power supply terminal T2, a p-channel transistor P1, an n-channel transistor N1, an inverter C1, an inverter C2, an access transistor A1, and an access transistor A2.

The power supply terminal T1 may receive a voltage Vdd. The voltage Vdd may be a positive power supply voltage.

The power supply terminal T2 may receive a voltage Vss. The voltage Vss may be a negative power supply voltage and/or a ground voltage.

A source terminal of the p-channel transistor P1 may be electrically connected to the power supply terminal T1 and a first source terminal of the inverter C2. A drain terminal of the p-channel transistor P1 may be electrically connected, through no intervening transistor, to a first source terminal of the inverter C1. A gate terminal of the p-channel transistor P1 may be electrically connected to a gate terminal of the access transistor A1 and a gate terminal of the access transistor A2.

A source terminal of the n-channel transistor N1 may be electrically connected to the power supply terminal T2 and a second source terminal of the inverter C2. A drain terminal of the n-channel transistor N1 may be electrically connected, not through any intervening transistor, to a second source terminal of the inverter C1.

A drain terminal of the access transistor A1 may be electrically connected to each of an output terminal of the inverter C1 (i.e., node X1 of the memory device 100) and an input terminal of the inverter C2. A drain terminal of the access transistor A2 may be electrically connected to each of an output terminal of the inverter C2 (i.e., node X2 of the memory device 100) and an input terminal the inverter C1.

The p-channel transistor P1 may be a p-channel metal-oxide-semiconductor field-effect transistor, or PMOS transistor. Each of the n-channel transistor N1, the access transistor A1, and the access transistor A2 may be an n-channel metal-oxide-semiconductor field-effect transistor, or NMOS transistor. Each of the inverter C1 and the inverter C2 may be a complementary metal-oxide-semiconductor (CMOS) unit.

The memory device 100 may include a word line WL1, a word line WL2, a bit line BL1, and a bit line BL2. The word line WL1, the word line WL2, the bit line BL1, and the bit line BL2 may be insulated from one another, for transmitting different signals.

The word line WL1 may be electrically connected to each of the gate terminal of the p-channel transistor P1, the gate terminal of the access transistor A1, and a gate terminal of the access transistor A2. The word line WL2 may be electrically connected to a gate terminal of the n-channel transistor N1. The bit line BL1 may be electrically connected to the source terminal of the access transistor A1. The bit line BL2 may be electrically connected to the source terminal of the access transistor A2.

The inverter C1 may include a p-channel transistor P2. A source terminal of the p-channel transistor P2 may be the first source terminal of the inverter C1 and may be electrically connected to the drain terminal of the p-channel transistor P1. The inverter C1 may include an n-channel transistor N2. A source terminal of the n-channel transistor N2 may be the second source terminal of the inverter C1 and may be electrically connected to the drain terminal of the n-channel transistor N1. The drain terminal of the p-channel transistor P2, the drain terminal of the n-channel transistor N2, the node X1 (i.e., the output terminal of the inverter C1), and the drain terminal of the access transistor A1 may be electrically connected to one another. The gate terminal of the p-channel transistor P2, the gate terminal of the n-channel transistor N2, the input terminal of the inverter C1, the node X2, and the drain terminal of the access transistor A2 may be electrically connected to one another.

The inverter C2 may include a p-channel transistor P3. A source terminal of the p-channel transistor P3 may be the first source terminal of the inverter C2 and may be electrically connected to the source terminal of the p-channel transistor P1. The inverter C2 may include an n-channel transistor N3. A source terminal of the n-channel transistor N3 may be the second source terminal of the inverter C2 and may be electrically connected to the source terminal of the n-channel transistor N1. The drain terminal of the p-channel transistor P3, the drain terminal of the n-channel transistor N3, the node X2 (i.e., the output terminal of the inverter C2), and the drain terminal of the access transistor A2 may be electrically connected to one another. The gate terminal of the p-channel transistor P3, the gate terminal of the n-channel transistor N3, the input terminal of the inverter C2, the node X1, and the drain terminal of the access transistor A1 may be electrically connected to one another.

Each of the p-channel transistors P2 and P3 may be a PMOS transistor. Each of the n-channel transistors N2 and N3 may be an NMOS transistor. One or more of the transistors in the memory device 100 may have one or more fin structures.

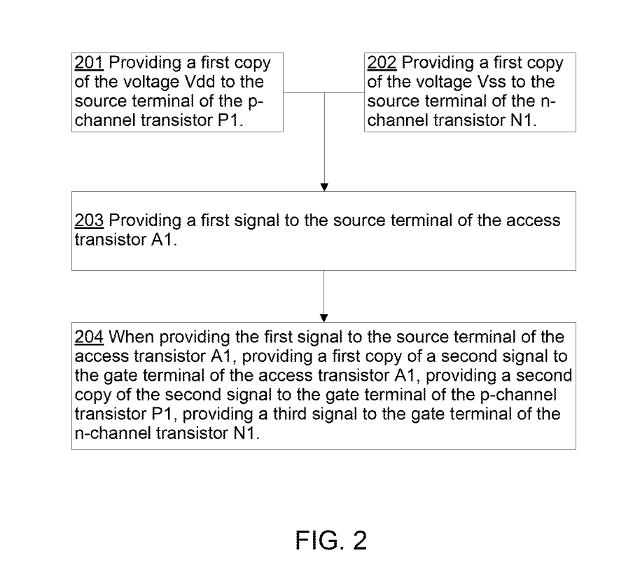

FIG. 2 shows a schematic flowchart that illustrates steps in a method for operating a memory device in accordance with one or more embodiments.

An embodiment may be related to a method for operating a memory device 100. The method may be related to a write operation of the memory device 100. The method may include the following steps: step 201, providing a first copy of the voltage Vdd to the source terminal of the p-channel transistor P1; step 202, providing a first copy of the voltage Vss to the source terminal of a n-channel transistor N1; step 203, providing a first signal to the source terminal of the access transistor A1; and step 204, when providing the first signal to the source terminal of the access transistor A1, providing a first copy of a second signal to the gate terminal of the access transistor A1, providing a second copy of the second signal to the gate terminal of the p-channel transistor P1, providing a third signal to a gate terminal of the n-channel transistor N1.

The steps 201 and 202 may be performed substantially simultaneously and may be performed continuously. The steps 203 and 204 may be performed substantially simultaneously and may be performed during the write operation.

The method may include providing a fourth signal (through the bit line BL2) to the source terminal of the access transistor A2 when providing the first signal (though the bit line BL1) to the source terminal of the access transistor A1. A value associated with the fourth signal may be unequal to (and may complement) a value associated with the first signal. In an embodiment, when the first signal corresponds to the value 1, the fourth signal may correspond to a value 0; when the first signal corresponds to the value 0, the fourth signal may correspond to a value 1.

The first copy of the second signal may cause the access transistor A1 to turn on. The second copy of the second signal may cause the p-channel transistor P1 to turn off. The third signal may cause the n-channel transistor N1 to turn off.

The method may include the following steps: in a write operation, setting the second signal (which is transmitted through the word line WL1) to have the first value and setting the third signal (which is transmitted through the word line WL2) to have the second value. The second value may be unequal to the first value. In an embodiment, the second signal may have a high or positive voltage and may have (or correspond to) the value 1, and the third signal may have a low or negative voltage and may have (or correspond to) the value 0.

In an embodiment, the method may include the following steps: when the node X1 of the memory device 100 corresponds to a first value (in a standby state), setting the first signal to have a second value (which is transmitted through the bit line BL1), setting the second signal (which is transmitted through the word line WL1) to have the first value, and setting the third signal (which is transmitted through the word line WL2) to have the second value to cause the node X1 of the memory to correspond to the second value in a write operation. The second value may be unequal to the first value.

In an embodiment, in a standby state, the node X1 may have a high or positive voltage and may correspond to the value 1, and the node X2 may have a low or negative voltage and may correspond to the value 0. A write operation may include setting the first signal to have the value 0, setting the second signal to have the value 1, and setting the third signal to have the value 0. Accordingly, the access transistor A1 may be turned on, the p-channel transistor P1 may be turned off, and the n-channel transistor N1 may be turned off. Since the p-channel transistor P1 is turned off, the voltage Vdd (e.g., a high or positive voltage) may have minimum or substantially no influence on node X1 during the write operation. Therefore, the node X1 may quickly (or immediately) discharge through the access transistor A1 and become corresponding to the value 0. Advantageously, the write operation may be performed substantially efficiently and/or accurately.

In an embodiment, the method may include the following steps: when the node X1 of the memory device 100 corresponds to a first value, setting the first signal to have a second value, setting the second signal to have the second value, and setting the third signal to have the first value to cause the node X1 of the memory to correspond to the second value. The second value may be unequal to the first value.

In an embodiment, in a standby state, the node X1 may have a low or negative voltage and may correspond to the value 0, and the node X2 may have a high or positive voltage and may correspond to the value 1. A write operation may include setting the first signal to have the value 1, setting the second signal to have the value 1, and setting the third signal to have the value 0. Accordingly, the access transistor A1 may be turned on, the p-channel transistor P1 may be turned off, and the n-channel transistor N1 may be turned off. Since the n-channel transistor N1 is turned off, the voltage Vss (e.g., a low or negative voltage) may have minimum or substantially no influence on node X1 during the write operation. Therefore, through the access transistor A1, the first signal may quickly (or immediately) charge the node X1 and drive the node to correspond to the value 1. Advantageously, the write operation may be performed substantially efficiently and/or accurately.

The method may include the following steps: providing a second copy of the voltage Vdd to the first source terminal of the inverter C2; and providing a second copy of the voltage Vss to the second source terminal of the inverter C2. Therefore, operation of the memory device 100 may be maintained.

The method may include the following step: when providing the first signal to the source terminal of the access transistor A1, providing a third copy of the second signal to the gate terminal of the access transistor A2. Therefore, the fourth signal may be provided through the access transistor A2 to the node X2, for maintaining operation and/or sensitivity of the memory device 100.

According to embodiments, the memory device 100 may include the p-channel transistor P1 and the n-channel transistor N1 for isolating the node X1 from the voltages Vdd and Vss during write operations of the memory device 100. Therefore, a satisfactory write speed and/or a satisfactory write margin of the memory device 100 may be achieved. Advantageously, satisfactory performance of the memory device 100 (and satisfactory performance of an electronic device that includes the memory device) may be substantially attained.

A read operation of the memory device 100 may include the following steps: determining whether there is a voltage drop at the bit line BL2 with respect to the voltage Vdd; if there is a voltage drop at the bit line BL2, then the node X2 may correspond to the value 0, and the node X1 may correspond to the value 1; and if there is no voltage drop at the bit line BL2, then the node X2 may correspond to the value 1, and the node X1 may correspond to the value 0. The memory device 100 may have a satisfactory read margin.

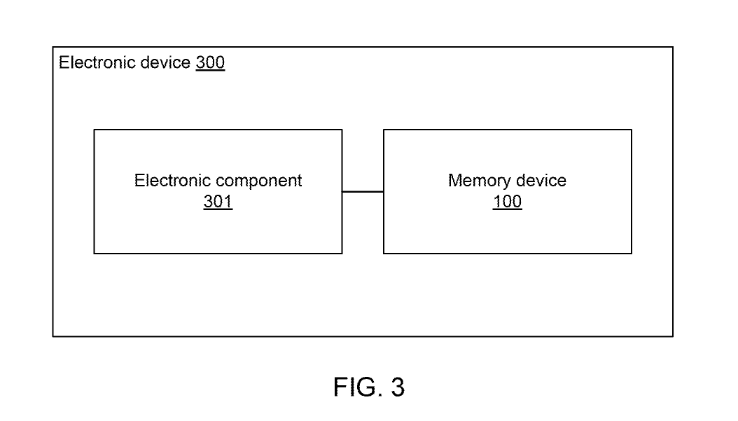

FIG. 3 shows a schematic block diagram that illustrates elements in an electronic device 300 in accordance with one or more embodiments. The electronic device 300 may include an electronic component 301 and the memory device 100. The memory device 100 may be electrically connected to the electronic component 301 and may have one or more of the above-discussed features.

In an embodiment, the electronic device 300 may be or may include one or more of a mobile phone, a tablet computer, a notebook computer, a netbook, a game console, a television, a video compact disc (VCD) player, a digital video disc (DVD) player, a navigation device, a camera, a camcorder, a voice recorder, an MP3 player, an MP4 player, a portable game device, etc.

In an embodiment, the electronic device 300 may be or may include an intermediate product (e.g., a mobile phone main board) or module.

According to embodiments, a memory device may include a p-channel transistor and an n-channel transistor that are configured to facilitate write operations of the memory device. Therefore, a satisfactory write speed and/or a satisfactory write margin of the memory device may be achieved. Advantageously, satisfactory performance of the memory device (and satisfactory performance of an electronic device that includes the memory device) may be substantially attained.

While some embodiments have been described as examples, there are alterations, permutations, and equivalents. It should also be noted that there are many alternative ways of implementing the methods and apparatuses. Furthermore, embodiments may find utility in other applications. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents.

What is claimed is:

1. A memory device comprising:
a first power supply terminal, which is configured to receive a first voltage;
a second power supply terminal, which is configured to receive a second voltage;
a first p-channel transistor, wherein a source terminal of the first p-channel transistor is electrically connected to the first power supply terminal;
a first n-channel transistor, wherein a source terminal of the first n-channel transistor is electrically connected to the second power supply terminal;
a first inverter, wherein a first source terminal of the first inverter is electrically connected, through no intervening transistor, to a drain terminal of the first p-channel transistor, and wherein a second source terminal of the first inverter is electrically connected to a drain terminal of the first n-channel transistor; and
a first access transistor, wherein a drain terminal of the first access transistor is electrically connected to an output terminal of the first inverter, and wherein a gate terminal of the first access transistor is electrically connected to a gate terminal of the first p-channel transistor.

2. The memory device of claim 1 comprising:
a first word line, which is electrically connected to both the gate terminal of the first access transistor and the gate terminal of the first p-channel transistor; and
a first bit line, which is electrically connected to the source terminal of the first access transistor.

3. The memory device of claim 2 comprising:
a second word line, which is electrically connected to a gate terminal of the first n-channel transistor.

4. The memory device of claim 1, wherein the first inverter comprises a second p-channel transistor, wherein a source terminal of the second p-channel transistor is the first source terminal of the first inverter and is electrically connected to the drain terminal of the first p-channel transistor.

5. The memory device of claim 1 comprising:
a second inverter, wherein a first source terminal of the second inverter is electrically connected to the source terminal of the first p-channel transistor, and wherein a second source terminal of the second inverter is electrically connected to the source terminal of the first n-channel transistor; and
a second access transistor, wherein a drain terminal of the second access transistor is electrically connected to both an output terminal of the second inverter and an input terminal the first inverter.

6. The memory device of claim 5, wherein the second inverter comprises a third p-channel transistor, wherein a source terminal of the third p-channel transistor is the first source terminal of the second inverter and is electrically connected to the source terminal of the first p-channel transistor.

7. The memory device of claim 5, wherein the first inverter comprises a second n-channel transistor, wherein a source terminal of the second n-channel transistor is the second source terminal of the first inverter and is electrically connected to the drain terminal of the first n-channel transistor.

8. The memory device of claim 7, wherein the second inverter comprises a third n-channel transistor, wherein a source terminal of the third n-channel transistor is the second source terminal of the second inverter and is electrically connected to the source terminal of the first n-channel transistor.

9. The memory device of claim 5, wherein a gate terminal of the second access transistor is electrically connected to both the gate terminal of the first p-channel transistor and the gate terminal of the first access transistor.

10. A method for operating a memory device, the method comprising:
providing a first copy of a first voltage to a source terminal of a first p-channel transistor, wherein the memory device comprises the first p-channel transistor;
providing a first copy of a second voltage to a source terminal of a first n-channel transistor, wherein the memory device comprises the first n-channel transistor;
providing a first signal to a source terminal of a first access transistor, wherein the memory device comprises the first access transistor, and wherein a first node of the memory device is electrically connected to a drain terminal of the first access transistor; and
when providing the first signal to the source terminal of the first access transistor, providing a first copy of a second signal to a gate terminal of the first access transistor, providing a second copy of the second signal to a gate terminal of the first p-channel transistor, and providing a third signal to a gate terminal of the first n-channel transistor.

11. The method of claim 10, wherein the first copy of the second signal causes the first access transistor to turn on, wherein the second copy of the second signal causes the first p-channel transistor to turn off, and wherein the third signal causes the first n-channel transistor to turn off.

12. The method of claim 10, comprising:
in a write operation, setting the second signal to have the first value and setting the third signal to have the second value, wherein the second value is unequal to the first value.

13. The method of claim 10, comprising:
when the first node of the memory device corresponds to a first value, setting the first signal to have a second value, setting the second signal to have the first value, and setting the third signal to have the second value to cause the first node of the memory to correspond to the second value, wherein the second value is unequal to the first value.

14. The method of claim 10, comprising:
when the first node of the memory device corresponds to a first value, setting the first signal to have a second value, setting the second signal to have the second value, and setting the third signal to have the first value to cause the first node of the memory to correspond to the second value, wherein the second value is unequal to the first value.

15. The method of claim 10, wherein the first node of the memory device is an output terminal of a first inverter and is electrically connected to an input terminal of a second inverter, wherein a second node of the memory device is an output of the second inverter and is electrically connected to an input terminal of the first inverter, wherein the memory device comprises the first inverter and the second inverter, wherein a first source terminal of the first inverter is electrically connected to a drain terminal of the first p-channel transistor, and wherein a second source terminal of the first inverter is electrically connected to a drain terminal of the first n-channel transistor.

16. The method of claim 15, wherein a first source terminal of the second inverter is electrically connected to a source terminal of the first p-channel transistor, and wherein a second source terminal of the second inverter is electrically connected to a source terminal of the first n-channel transistor.

17. The method of claim 15 comprising:
providing a second copy of the first voltage to a first source terminal of the second inverter; and
providing a second copy of the second voltage to a second source terminal of the second inverter.

18. The method of claim 10 comprising:
when providing the first signal to the source terminal of the first access transistor, providing a third copy of the second signal to a gate terminal of a second access transistor, wherein the memory device comprises the second access transistor.

19. The method of claim 10 comprising:
providing the second signal through a first word line, wherein the first word line is electrically connected to each of the gate terminal of the first p-channel transistor and the gate terminal of the first access transistor; and
providing the third signal though a second word line, wherein the second word line is electrically connected to the gate terminal of the first n-channel transistor and is insulated from the first word line.

20. An electronic device comprising:
an electronic component; and
a memory device electrically connected to the electronic component and comprising:
a first power supply terminal, which is configured to receive a first voltage;
a second power supply terminal, which is configured to receive a second voltage;
a first p-channel transistor, wherein a source terminal of the first p-channel transistor is electrically connected to the first power supply terminal;
a first n-channel transistor, wherein a source terminal of the first n-channel transistor is electrically connected to the second power supply terminal;
a first inverter, wherein a first source terminal of the first inverter is electrically connected, without through any intervening transistor, to a drain terminal of the first p-channel transistor, and wherein a second source terminal of the first inverter is electrically connected to a drain terminal of the first n-channel transistor; and
a first access transistor, wherein a drain terminal of the first access transistor is electrically connected to an output terminal of the first inverter, and wherein a gate terminal of the first access transistor is electrically connected to a gate terminal of the first p-channel transistor.
